(19) United States
(12) Patent Application Publication
(10) Pub. No.: US 2025/0283205 A1
(43) Pub. Date: Sep. 11, 2025

(54) MANUFACTURING OF MESAS USING DEPOSITED LAYER FOR SUBSTRATE SUPPORTS

(71) Applicant: Applied Materials, Inc., Santa Clara, CA (US)

(72) Inventors: Katherine WOO, Santa Clara, CA (US); Jennifer Y. SUN, Mountain View, CA (US); Wenhao ZHANG, San Jose, CA (US); Jian LI, Fremont, CA (US); Juan C. ROCHA, San Carlos, CA (US)

(21) Appl. No.: 18/599,463

(22) Filed: Mar. 8, 2024

(51) Int. Cl. C23C 14/04; C23C 14/50

(52) U.S. Cl. CPC C23C 14/04; C23C 14/50

(57) ABSTRACT

Embodiments of the present disclosure generally relate to forming mesas on substrate supports. In some embodiments, the substrate supports include heaters or electrostatic chucks. More specifically, embodiments relate to using physical vapor deposition (PVD) to reform damaged mesas on substrate supports by adding new layers of material. In one embodiment, a method of forming features on a substrate support is provided. The method includes depositing a first layer on a first surface of a support body of a substrate support. The method further includes forming a plurality of features in the first layer by removing portions of the first layer. The plurality of features include a plurality of valleys between a plurality of peaks. A ratio of a thickness of the support body to a thickness of the first layer is greater than 10:1.

### BACKGROUND

### Field

Embodiments of the present disclosure generally relate to semiconductor processing. More specifically, embodiments relate to forming mesas on substrate supports.

### Description of the Related Art

Various semiconductor processing techniques implement substrate supports that may act as heaters and electrostatic chucks. These substrate supports have mesas to support the substrate during processing. Processing of the substrate can cause the mesas to wear down. Accordingly, the mesas must be repaired to continue using the substrate support in processing. Substrate supports acting as heater and electrostatic chucks have electronics such as RF meshes and electrodes disposed within the substrate support. The distance from where the substrate is placed on the substrate support and the electronics disposed within the substrate support is critical to processing performance.

Therefore, improved techniques for forming substrate mesas are needed.

### SUMMARY

In one embodiment, a method of forming features on a substrate support is provided. The method includes depositing a first layer on a first surface of a support body of a substrate support. The method further includes forming a plurality of features in the first layer by removing portions of the first layer. The plurality of features include a plurality of valleys between a plurality of peaks. A ratio of a thickness of the support body to a thickness of the first layer is greater than 10:1.

In another embodiment, a method of forming mesas on a substrate support is provided. The method includes removing a first layer disposed on a first surface of a support body of a substrate support. The first layer includes a plurality of first mesas formed on the support body. The method further includes depositing a second layer on the first surface of the support body, and forming a plurality of second mesas in the second layer.

In another embodiment, a substrate support is provided. The substrate support includes a support body having a first surface, and a plurality of mesas formed in a first layer. The plurality of mesas are disposed on the first surface of the support body. A ratio of a thickness of the support body to a thickness of the first layer is greater than 10:1. The substrate support further includes a RF mesh disposed in the support body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic, side view of a processing chamber with a substrate support, according to embodiments.

FIG. 2A is a schematic, side view of a support body of a substrate support, according to embodiments.

FIG. 2B is a schematic, side view of a support body of a substrate support, according to embodiments.

FIG. 2C is a schematic, side view of a support body of a substrate support, according to embodiments.

FIG. 3 is a flow diagram of a method for repairing a substrate support, according to embodiments.

FIGS. 4A-4D are schematic, cross-sectional views of a substrate support during a method, according to the embodiments

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to forming mesas on substrate supports. In some embodiments, the substrate supports include heaters or electrostatic chucks. More specifically, embodiments relate to using physical vapor deposition (PVD) to reform damaged mesas on substrate supports by adding new layers of material.

Mesas are present on substrate supports to support a substrate without the substrate lying flat in complete contact with the substrate support. Mesas can wear down with repeated use in process chambers. Because substrate supports are expensive, repair is preferable to replacement. Normally, the mesas are formed on the substrate support at the time of fabrication of the substrate support. The method of repair is to resurface the mesas by grinding and reforming the mesas. The damaged mesas are grinded away, and new mesas are formed from bulk material of the substrate support. Grinding the mesas reduces buffer material between a top surface of the mesas and a RF mesh disposed in the substrate support. The buffer material prevents leakage of voltage and prevents drifting of the electrical charge during chucking. The buffer material limits the amount of times the mesas may be replaced in the life cycle of the substrate support.

Various techniques described herein allow for repeated replacement of mesas during the life cycle of the substrate support. The mesas are partially or fully formed from a physical vapor deposition (PVD) material layer. The mesas made of PVD material may be removed and replaced without affecting the amount of buffer material between the RF mesh and the mesas. The PVD material layer may provide additional properties to enhance the substrate support. By having near unlimited mesa replacement, the cost of ownership of the substrate support is significantly reduced. The use of PVD to form the mesas allows for optimization to reduce current drift over prolonged use of chucking prior to stabilization.

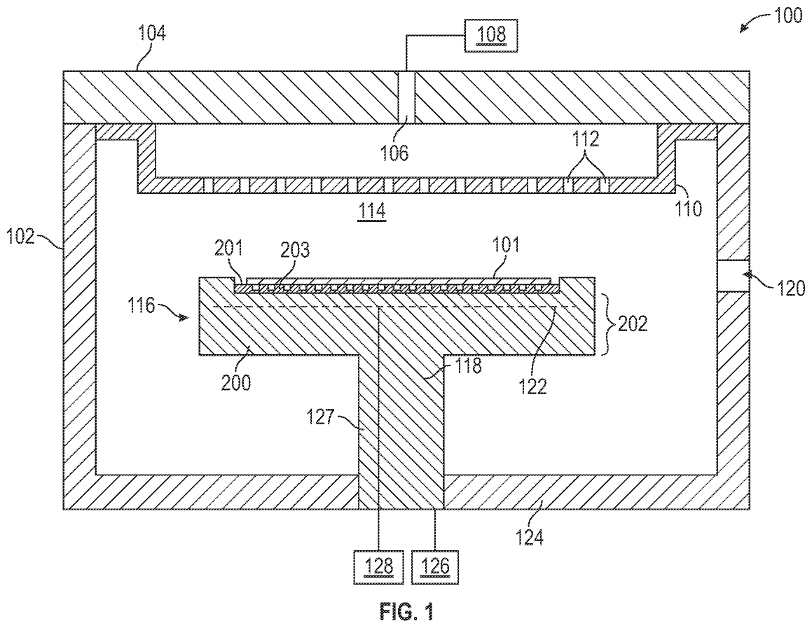

FIG. 1 illustrates a schematic view of a process chamber 100 according to some embodiments of the disclosure. The process chamber 100 includes a chamber body 102 and a lid 104 defining a process volume 114 therein. A bottom 124 of the chamber body 102 is opposite the lid 104. A port 106 is formed through the lid 104. A gas source 108 is in fluid communication with the port 106. A showerhead 110 is coupled to the lid 104. A plurality of openings 112 are formed through the showerhead 110. The gas source 108 is in fluid communication with the process volume 114 via the port 106 and the openings 112.

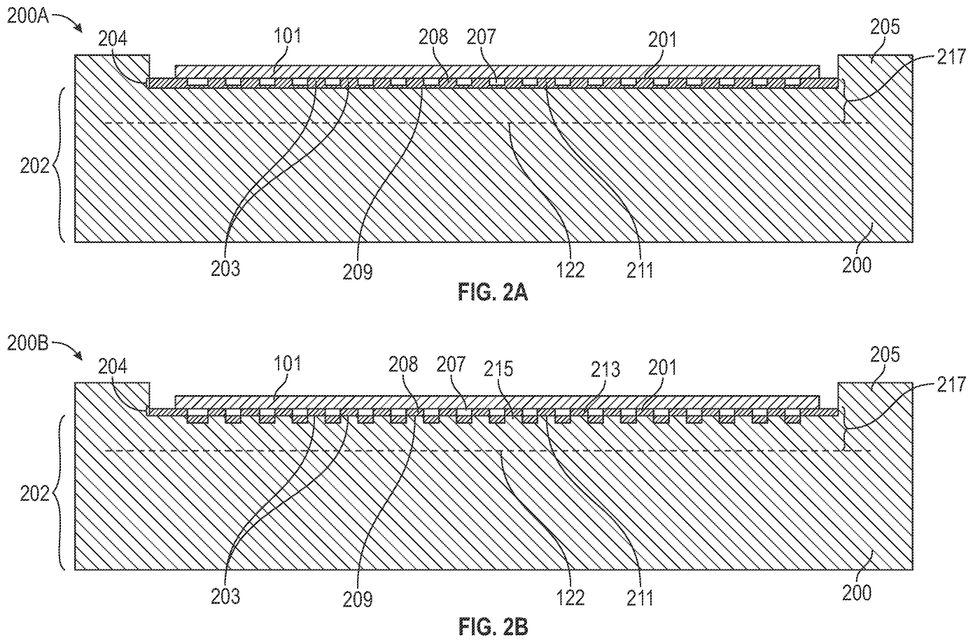

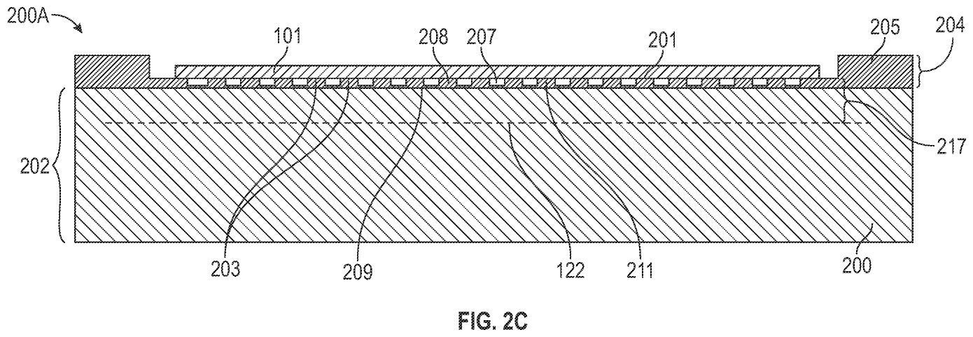

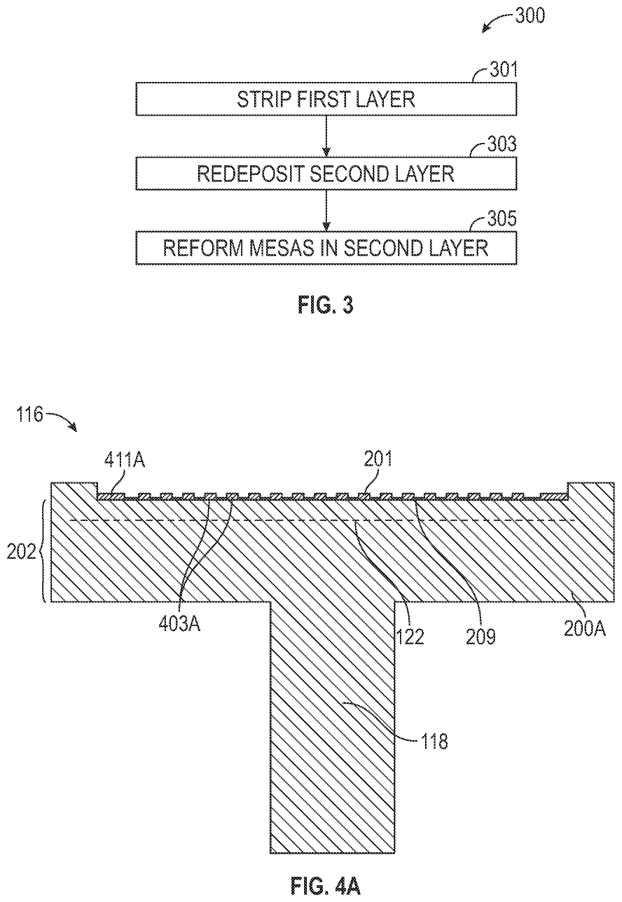

A substrate support 116 is moveably disposed in the process volume 114 opposite the lid 104. The substrate support 116 includes a support body 200 disposed on a stem 118. The support body 200 includes a support surface 201 disposed opposite the stem 118 and facing the showerhead 110. In some embodiments, the support body 200 includes a heater or an electrostatic chuck. The support body 200 is formed from a bulk material. The support body 200 may include aluminum nitride (AlN), boron nitride (BN), or a similar material. The support body 200 may have a thickness 202 ranging from 15 mm to 75 mm, such as 25 mm to 52 mm. The support surface 201 includes a plurality of mesas 203, which are further described in FIGS. 2A and 2B. Although the techniques disclosed herein are described with respect to forming mesas 203 on a substrate support 116, any of the techniques described herein may be implemented to form any type of feature on a substrate support 116, including mesas, ledges, pockets, or tabs. An opening 120 is formed through the chamber body 102 between the lid 104 and the bottom 124. During operation, a substrate 101 is loaded onto the support surface 201 through the opening 120. An actuator 126 is coupled to the substrate support 116 to move the substrate support 116 toward and away from the showerhead 110 for loading and processing the substrate 101 thereon.

An RF mesh 122 is disposed within the support body 200. One or more portions of the RF mesh 122 are disposed in a plane that is substantially perpendicular to the support surface 201. In some embodiments, a heating element is disposed within the support body 200. The heating element and RF mesh 122 may be used to heat the substrate 101 or electrostatically chuck the substrate 101. The heating element may be disposed below the RF mesh 122 and may be substantially perpendicular to the support surface 201. The RF mesh 122 is a set distance away from the support surface 201 described further in FIGS. 2A and 2B. The RF mesh 122 is connected to one or more RF leads 127. The RF leads 127 are coupled to an RF power source 128. The RF power source 128 provides RF power to the RF mesh 122. Although the processing chamber 100 described herein is provided as an example of a chamber with which the substrate support 116 can be implemented, in various embodiments, the substrate support 116 can be implemented with other types of processing chambers.

FIG. 2A is a schematic, side view of a first support body 200A. The first support body 200A is shown in the process chamber 100 in FIG. 1. As described above, the support body 200A includes the support surface 201, the mesas 203, and the RF mesh 122. The support body 200A further includes an edge ring 205. In some embodiments, the edge ring 205 is formed from the support body 200A and extends around the mesas 203. The edge ring 205 also surrounds the substrate 101 when the substrate 101 is placed on the mesas 203. The substrate 101 is placed on the support surface 201 of the mesas 203. The support surface 201 is part of the mesas 203.

Each of the one or more mesas 203 is formed between two or more valleys 207. Each of the one or more valleys 207 may be formed by removing material from the support surface 201 between each of the one or more mesas 203. The mesas 203 may be a dimple pattern. The mesas 203 may be an isolated raised feature. The feature may be rectangular, square, round, etc. The pattern can have any number of mesas 203 at any coordinates within the support surface 201. The mesas 203 prevent the substrate from contacting a first surface 209 of the support body 200A.

In FIG. 2A, the mesas 203 are formed from a deposited layer 211. In some embodiments, the deposited layer 211 may be deposited by physical vapor deposition (PVD). Other methods for depositing the deposited layer 211 include, for example, atomic layer deposition (ALD), thermal spray (e.g. suspension plasma spray, vacuum plasma spray, or similar processes), sol-gel, and other dense, thick film deposition techniques. The deposited layer 211 may include at least one of aluminum nitride (AlN), Aluminum oxynitride (AIₓO_{y}N_{z}), low vapor pressure compounds or a similar ceramic material. Low vapor pressure compounds include single metal oxides (M-O), single metal oxyfluorides (M-O-F), single metal fluorides (M-F), double metal oxides (M1M2O), double metal oxyfluorides (M1M2OF), double metal fluorides (M1M2F), triple metal oxides (M1M2M30), triple metal oxyfluorides (M1M2M3OF), and single metal fluorides (M1M2M3F). The metals (e.g., M, M1, M2, M3) used in the low vapor pressure compounds may include, for example, magnesium (Mg), erbium (Er), strontium (Sr), calcium (Ca), yttrium (Y), barium (Ba), lanthanum (La), samarium (Sm), and similar metals. The material of the deposited layer 211 provides benefits to the mesas 203 such as thermal, mechanical, and physical property improvements compared to the bulk material. In some embodiments, the deposited layer 211 includes multiple layers that form multi-compositional mesas 203.

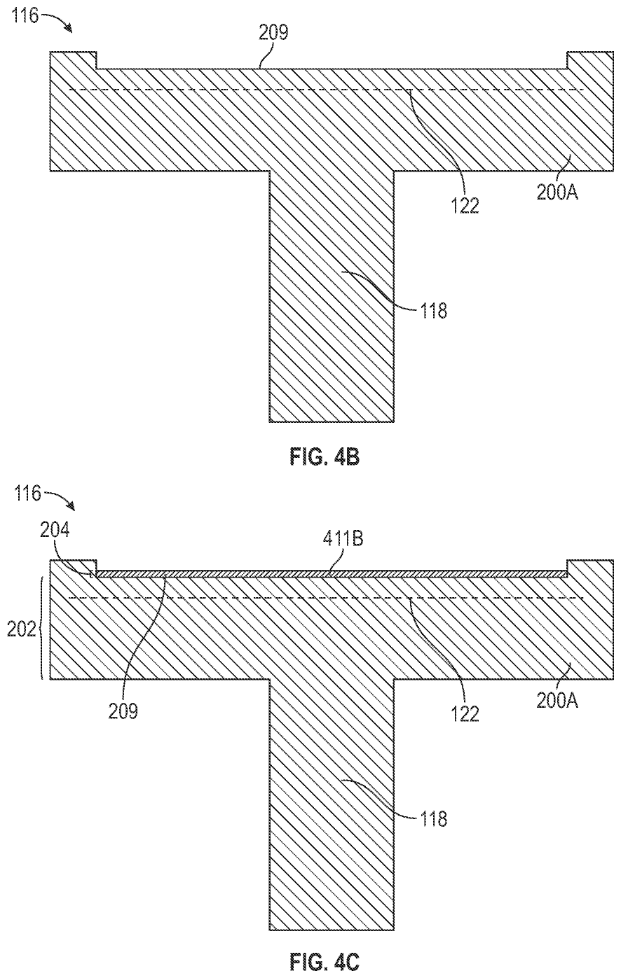

In some embodiments, the deposited layer 211 is made of the same material as the bulk material of the support body 200A. In other embodiments, the deposited layer 211 includes a material different to the bulk material of the support body 200A. In some embodiments, the deposited layer 211 includes multiple layers of different materials, for example, in order to reduce a mismatch of the coefficients of thermal expansion (CTEs) between the support body 200 and the mesas 203. For example, in some embodiments, if the support body 200 and the mesas 203 have different CTEs, one or more layers having CTE(s) that are in between the CTE of the support body 200 and the CTE of the mesas 203 may be disposed between the support body 200 and the mesas 203 in order to more gradually transition between the different CTEs. In some embodiments, the deposited layer 211 has multiple layers tuned for intended processing temperature. The deposited layer 211 may be a material to give the mesas 203 additional properties, which may be tailored to processes performed in the process chamber 100, for example, reducing leakage current from the RF mesh 122 or reduce backside substrate scratching. In some embodiments, the deposited layer 211 is partially or fully fluorinated to avoid further build-up of fluoride during processing. The deposition of the deposited layer 211 is described in FIG. 3. The deposited layer 211 forms both the peaks 208 and the valleys 207 of the plurality of mesas 203. The deposited layer 211 covers both the peaks 208 and valleys 207. The first surface 209 is covered by the deposited layer 211 across the plurality of mesas 203. The bulk material is covered by the deposited layer 211 across the plurality of mesas 203. The first surface 209 is flat. Benefits of the support body 200A include design freedom to change the pattern of the mesas 203 every repair cycle.

Creating the valleys 207 forms peaks 208 on each of the mesas 203. The peaks 208 form the support surface 201. The valleys 207 are formed by removing portions of the deposited layer 211. The bottom of the valleys 207 includes a portion of the deposited layer 211 such that a portion of the support body 200 is not removed to form the mesas 203. The support body 200 is completely protected by the deposited layer 211 across the mesas 203. The deposited layer 211 has a layer thickness 204. The layer thickness 204 is governed by a height of the mesas 203. The height of the mesas 203 is defined by a distance between the valleys 207 and the peaks 208. In various embodiments, the height of the mesas is greater than about 10% of the layer thickness 204, such as about 90% to 10%, such as 75% to 15%, such as 70% to 35%. The layer thickness 204 ranges from 1 micron to 2500 microns, such as 10 microns to 1000 microns, such as 20 microns to 500 microns. In some embodiments, a ratio of the thickness 202 of the support body 200 to the layer thickness 204 is greater than 10:1, such as ranging from about 20:1 to about 50,000:1, such as about 100:1 to 5,000:1.

FIG. 2B is a schematic, side view of a second support body 200B. The second support body 200B includes the support surface 201, the mesas 203, the RF mesh 122, and the edge ring 205. In FIG. 2B, the mesas 203 are formed from the deposited layer 211 and the support body 200B. The first surface 209 follows a pattern formed by the second portion 215 of the mesas 203. The deposited layer 211 form a portion of the mesas 203. A first portion 213 of the mesas 203 is formed from the deposited layer 211. The deposited layer 211 may be one of the deposited layers 211 described above. The deposited layer 211 may include any of the materials and properties described above. A second portion 215 of the mesas 203 is formed from the support body 200B. The first surface 209 of the support body 200B is a top surface of the second portion 215 and contacts the first portion 213. The patterns of the first portion 213 and the second portion 215 substantially match one another. The support surface 201 is a top surface of the first portion 213 of the mesas 203. In some embodiments, the first portion 213 and second portion 215 have the same thickness. In other embodiments, the first portion 213 and second portion 215 have different thicknesses. In some embodiments, the first portion 213 has a constant thickness. Since the support body 200B forms a portion of the mesas 203, the mesas design cannot be changed during reforming. The support body 200B has the benefit of shorter repair time and requiring less material to form new mesas 203. The mesas 203 are formed in the same way as described above, except the support body 200B forms a second portion 215 of the mesas 203. The deposited layer 211 covers the plurality of the second portion 215 such that the support body 200B is not removed to form the mesas 203. The support body 200B is completely protected by the deposited layer 211 across the mesas 203.

As described above, the RF mesh 122 is disposed in the support body 200. In order to function properly, the RF mesh 122 is a set distance 217 from the support surface 201. The distance from the support surface 201 allows material from both the mesas 203 and support body 200 to separate the RF mesh 122 and the substrate 101 to be placed on the support surface 201. The distance causes the beneficial properties described above. The set distance 217 varies between substrates, processes, and substrate supports. The set distance 217 is about 0.5 mm to about 2.5 mm, such as 1 mm. As the substrate support 116 is used in the process chamber 100, the mesas 203 are worn down. The mesas 203 may be replaced when the mesas 203 negatively affect processing performance. Examples of issues caused by defective mesas 203 include backside damage to the substrate 101 such as backside scratches, loss of deposition uniformity on the substrate 101, and other similar issues.

FIG. 2C is a schematic, side view of the support body 200A, according to embodiments. FIG. 2C illustrates embodiments in which the edge ring 205 is formed from the deposited layer 211 and extends around the mesas 203. FIGS. 2A and 2B illustrate embodiments in which the edge ring 205 is formed in the support body 200. The layer thickness 204 of the deposited layer 211 includes the edge ring 205 when the edge ring 205 is formed from the deposited layer 211. When the mesas 203 are reformed as described in FIG. 3, the edge ring 205 may be reformed as well.

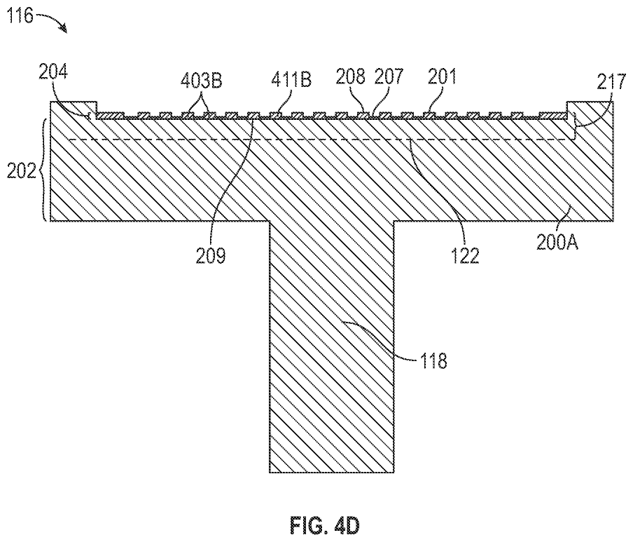

FIG. 3 is a flow diagram describing steps of a method 300 of reforming mesas 203. FIGS. 4A-4D illustrate the substrate support 116 during the method 300. Although the techniques are described with respect to forming mesas 203 on a substrate support 116, the techniques described herein may be implemented to form any type of feature on a substrate support 116, including mesas, ledges, pockets, or tabs

Prior to operation 301, FIG. 4A illustrates the substrate support 116 having first mesas 403A that have been worn down, for example, during semiconductor processing. The first mesas 403A need to be reformed. In various embodiments, the first mesas 403A can no longer support the substrate 101 during processing. Examples of issues caused by defective first mesas 403A include backside damage to the substrate 101, such as backside scratches, loss of deposition uniformity on the substrate 101, and other similar issues. In some embodiments, the determination of whether the first mesas 403A need to be reformed is an automated process. A controller connected to the process chamber 100 has sensors to analyze the first mesas 403A. The controller makes a determination using the factors above to determine when the first mesas 403A need to be reformed. In some embodiments, as shown in FIGS. 2A and 4A, the first mesas 403A are formed entirely out of a first layer 411A which corresponds to the deposited layer 211. In other embodiments, such as shown in FIG. 2B, the first mesas 403A are partially formed out of the deposited layer 211 and partially formed out of the support body 200B.

At operation 301, the first layer 411A is removed. In some embodiments, the first layer is formed by PVD, atomic layer deposition (ALD), thermal spray (e.g. suspension plasma spray, vacuum plasma spray, or similar processes), sol-gel, and other dense, thick film deposition techniques. The first layer 411A is removed using at least one of a mechanical process, like machining, bead blasting, laser patterning, etc., and a chemical process, like lithography or etching. FIG. 4B shows the substrate support 116 with the first layer 411A removed. As shown in FIG. 4B, the first mesas 403A are entirely formed from the first layer 411A. The first surface 209 of the support body 200A is exposed. The first surface 209 is flat. In embodiments with the support body 200B, the first mesas 403A are partially formed with the first layer 411A and partially formed with the bulk material of the support body 200B. The first surface 209 of the support body 200B is exposed. The first surface 209 forms the second portion 215 of the first mesas 403A. The second portion 215 remains while the first portion 213 is removed.

At operation 303, a second layer 411B is deposited. The second layer 411B is deposited using PVD, atomic layer deposition (ALD), thermal spray (e.g. suspension plasma spray, vacuum plasma spray, or similar processes), sol-gel, and other dense, thick film deposition techniques. The second layer 411B also corresponds to the deposited layer 211. In some embodiments, second layer 411B includes multiple layers. FIG. 4C shows the substrate support 116 with the second layer 411B deposited. FIG. 4C shows a uniform thickness second layer 411B disposed on the support body 200A. The second mesas 403B are to be formed from the second layer 411B. In embodiments that implement the support body 200B, the second layer 411B is disposed on the pattern formed by the second portion 215 to form the second mesas 403B. In some embodiments, the substrate support 116 is first formed, and operation 301 is skipped, since no first layer 411A is present on the support body 200. In such embodiments, at operation 303, a layer of material is deposited on the support body 200A for the first time. In some embodiments, a layer of material is deposited on the support body 200B for the first time. Performing operation 303 on the original manufactured substrate support 116 allows the method 300 to be performed to refurbish the substrate support 116 later.

At operation 305, the second mesas 403B are formed in the second layer 411B. In some embodiments, the mesas 203 are formed using bead blasting, laser, photolithography, or other machining techniques. Bead blasting uses a pattern transfer to pattern the second mesas 403B. The pattern transfer uses a mask to block beads from removing material in sections with the mesa 203 and allow beads to remove material to form valleys 207 and peaks 208. The valleys 207 are formed by removing portions of the second layer 411B. The bottom of the valleys 207 includes a portion of the second layer 411B such that the support body 200 is not removed to form the second mesas 403B. In embodiments where the edge ring 205 is formed from the first layer 411A, the edge ring 205 may be reformed from the second layer 411B. FIG. 4D shows the substrate support 116 with the second mesas 403B formed. The second mesas 403B have the support surface 201, which supports the substrate 101. The support surface 201 is the set distance 217 away from the RF mesh 122. In some embodiments with the support body 200B, the pattern of the second portion 215 is the same as the pattern of the second mesas 403B. The second layer 411B then does not need to be machined as the uniform thickness completes the second mesas 403B. In other embodiments, the second layer 411B disposed on the support body 200B is machined as described above.

Multiple substrate supports 116 can be repaired at the same time using the method 300. For example, multiple substrate supports 116 can be placed into a batch chamber to have the method 300 performed. Performing the method 300 on multiple substrate supports 116 at the same time further reduces the time and cost of refurbishing the mesas 203.

In summation, embodiments of the present disclosure generally relate to mesas on substrate supports. The substrate supports can include heaters or electrostatic chucks. More specifically, embodiments relate to using physical vapor deposition to reform damaged mesas on substrate supports. The method allows for near unlimited mesa replacement in the life cycle of the substrate support. The mesas are partially or fully formed from a physical vapor deposition (PVD) material layer. Benefits include the mesas being removed and replaced without affecting the amount of material between the RF mesh and mesa, and endowing additional properties to enhance the substrate support provided by the PVD material. The cost of ownership of the substrate support is significantly reduced due to the mesas being replaceable without affecting the rest of the substrate support. The use of PVD to form the mesas allows for optimization to reduce current drift over prolonged use of chucking prior to stabilization. Ease of replacing mesas will reduce backside scratching of substrates during processing.

While the foregoing is directed to embodiments of the present disclosure, other and further embodiments of the disclosure may be devised without departing from the basic scope thereof, and the scope thereof is determined by the claims that follow.

What is claimed is:

1. A method of forming features on a substrate support, comprising:
depositing a first layer on a first surface of a support body of a substrate support; and
forming a plurality of features in the first layer by removing portions of the first layer, wherein the plurality of features comprise a plurality of valleys between a plurality of peaks, wherein a ratio of a thickness of the support body to a thickness of the first layer is greater than 10:1.

2. The method of claim 1, wherein a height of the plurality of features is greater than about 10% of a thickness of the first layer.

3. The method of claim 1, wherein the first layer comprises at least one of aluminum nitride, or aluminum oxynitride, and the first layer is deposited by physical vapor deposition (PVD), thermal spray, sol-gel, or atomic layer deposition (ALD).

4. The method of claim 1, wherein the support body comprises aluminum nitride or boron nitride.

5. The method of claim 1, wherein an edge ring is formed from the first layer along with the plurality of features, the edge ring disposed on the support body and surrounding the plurality of features.

6. The method of claim 1, wherein the first surface of the support body includes a pattern that corresponds to the plurality of features.

7. A method of forming mesas on a substrate support, comprising:
removing a first layer disposed on a first surface of a support body of a substrate support, the first layer including a plurality of first mesas formed on the support body;
depositing a second layer on the first surface of the support body; and
forming a plurality of second mesas in the second layer.

8. The method of claim 7, wherein a ratio of a thickness of the support body to a thickness of the second layer is greater than 10:1.

9. The method of claim 7, wherein a height of the plurality of second mesas is greater than about 10% of a thickness of the second layer.

10. The method of claim 7, wherein the first layer and the second layer comprise at least one of aluminum nitride or aluminum oxynitride, and the first layer and the second layer are deposited by physical vapor deposition (PVD).

11. The method of claim 7, wherein the support body comprises aluminum nitride.

12. The method of claim 7, wherein an edge ring is formed from the second layer along with the plurality of second mesas, the edge ring disposed on the support body and surrounding the plurality of second mesas.

13. The method of claim 7, wherein the first surface of the support body includes a pattern that corresponds to the plurality of second mesas.

14. A substrate support, comprising:
a support body having a first surface;
a plurality of mesas formed in a first layer disposed on the first surface of the support body, wherein a ratio of a thickness of the support body to a thickness of the first layer is greater than 10:1; and
a RF mesh disposed in the support body.

15. The substrate support of claim 14, wherein a height of the plurality of mesas is greater than about 10% of a thickness of the first layer.

16. The substrate support of claim 14, wherein the support body comprises at least one of a heater or an electrostatic chuck.

17. The substrate support of claim 14, wherein the first layer comprises at least one of aluminum nitride or aluminum oxynitride, and the first layer is deposited by physical vapor deposition (PVD).

18. The substrate support of claim 14, further comprising an edge ring formed from the first layer, the edge ring disposed on the support body and surrounding the plurality of mesas.

19. The substrate support of claim 14, wherein the plurality of mesas comprise:
a first portion comprising the first layer; and
a second portion formed on the first surface of the support body, wherein the first portion is disposed on the second portion.

20. The substrate support of claim 14, further comprising one or more layers disposed between the support body and the first layer, wherein the one or more layers have a coefficient of thermal expansion (CTE) that is between a first CTE of the support body and a second CTE of the first layer.
